(19) United States
(12) Patent Application Publication
(10) Pub. No.: US 2013/0149803 A1
(43) Pub. Date: Jun. 13, 2013

(54) METHOD OF FABRICATING ORGANIC LIGHT EMITTING DIODE

(71) Applicants: Jaehyun MOON, Daejeon (KR); Jeong Ik Lee, Gyeonggi-do (KR); Doo-Hee Cho, Daejeon (KR); Seung Koo Park, Daejeon (KR); Hye Yong Chu, Daejeon (KR); Joo Hyun Hwang, Seoul (KR); Jin Wook Shin, Incheon (KR); Jun-Han Han, Daejeon (KR); Chul Woong Joo, Seoul (KR); Jin Woo Huh, Daejeon (KR); Byoung Gon Yu, Chungcheongbuk-do (KR)

(72) Inventors: Jaehyun MOON, Daejeon (KR); Jeong Ik Lee, Gyeonggi-do (KR); Doo-Hee Cho, Daejeon (KR); Seung Koo Park, Daejeon (KR); Hye Yong Chu, Daejeon (KR); Joo Hyun Hwang, Seoul (KR); Jin Wook Shin, Incheon (KR); Jun-Han Han, Daejeon (KR); Chul Woong Joo, Seoul (KR); Jin Woo Huh, Daejeon (KR); Byoung Gon Yu, Chungcheongbuk-do (KR)

(73) Assignee: ELECTRONICS AND TELECOMMUNICATIONS RESEARCH INSTITUTE, Daejeon (KR)

(21) Appl. No.: 13/606,127

(22) Filed: Sep. 7, 2012

(30) Foreign Application Priority Data
Dec. 12, 2011 (KR) 10-2011-0133026

(51) Int. Cl. H01L 51/56

(52) U.S. Cl. 438/29; 257/E51.018

(57) ABSTRACT

Provided is a method of fabricating an organic light emitting diode. The method may include preparing a substrate, forming a textured portion on the substrate, the textured portion including protruding patterns randomly and irregularly arranged on the substrate, forming a planarization layer on the substrate to planarize the substrate formed with the textured portion, forming a first electrode on the planarization layer, forming an organic light emitting layer on the first electrode, and forming a second electrode on the organic light emitting layer.

### CROSS-REFERENCE TO RELATED APPLICATIONS

This U.S. non-provisional patent application claims priority under 35 U.S.C. §119 to Korean Patent Application No. 10-2011-0133026, filed on Dec. 12, 2011, in the Korean Intellectual Property Office, the entire contents of which are hereby incorporated by reference.

### BACKGROUND OF THE INVENTION

Embodiments of the inventive concepts relate to an organic light emitting diode, and in particular, to a method of fabricating an organic light emitting diode.

There is increasing demands for small-sized, lightweight, thin and high-resolution display devices. Organic light emitting devices have been developed to satisfy the demands and provide a surface luminous device for replacing incandescent and fluorescent lamps.

An organic light emitting diode (OLED) is one type of self-luminous device configured to generate a light using an excitation of an organic light emitting material. Since the OLED can be operated without an additional light source, it has a technical advantage of low power consumption. In addition, the OLED has various technical advantages, such as wide viewing angle, fast response time, small thickness, low fabrication cost, and high contrast.

The OLED may include a substrate, a first electrode, a second electrode, and an organic light emitting layer interposed between the first and second electrodes. In the organic light emitting layer, holes and electrons supplied from the first and second electrodes may be recombined in the light emitting organic layer to generate a light. A wavelength or color of a light emitted from the OLED can be changed depending on the kind of a material constituting the organic light emitting layer.

Accordingly, the OLED is in the spotlight as next-generation flat-panel display device and illumination sources. However, the conventional OLED devices have suffered from low external luminous efficiency of 20% or less. For example, due to difference in refractive indices, a light emitted outward from the organic light emitting layer through a transparent substrate may be attenuated.

### SUMMARY

Embodiments of the inventive concepts provide a method of easily fabricating an organic light emitting diode with high light extraction efficiency.

According to example embodiments of the inventive concepts, a method of fabricating an organic light emitting diode may include preparing a substrate, forming a textured portion on the substrate, the textured portion including protruding patterns randomly and irregularly arranged on the substrate, forming a planarization layer on the substrate to planarize the substrate formed with the textured portion, forming a first electrode on the planarization layer, forming an organic light emitting layer on the first electrode, and forming a second electrode on the organic light emitting layer.

In example embodiments, the forming of the textured portion may include dispersing nanoparticles on the substrate to initiate the de-wetting of a polymer film, forming a polymer layer on the nanoparticles, thermally treating the polymer layer to form a polymer mask, and etching the substrate using the polymer mask as an etching mask.

In example embodiments, the dispersing of the nanoparticles may include mixing the nanoparticles with a highly volatile solvent to prepare a nanoparticle-containing solution, and dispersing the nanoparticle-containing solution onto the substrate.

In example embodiments, the dispersing of the nanoparticles may be performed, at a temperature ranging from 200° C. to 600° C., using a de-wetting effect of a metallic thin film.

In example embodiments, the metallic thin film may have a thickness ranging from 10 nm to 50 nm.

In example embodiments, the thermal treatment may be performed at a temperature higher than the glass transition temperature of the polymer.

In example embodiments, the nanoparticle may include one of metal compounds or metals.

In example embodiments, a size of the nanoparticle may range from 10 nm to 50 nm.

In example embodiments, the spacing between the nanoparticles may range from 100 nm to 2000 nm.

In example embodiments, a thickness of the polymer layer may range from 50 nm to 2000 nm.

In example embodiments, the polymer layer may include at least one of polystyrene (PS), polycarbonate (PC), poly(methyl methacrylate) (PMMA), polyethylene type resin, polyacrylic resin, polyvinyl chloride (PVC), polyvinylpyrrolidone (PVP), polyamide type resin, or epoxy type resin.

In example embodiments, the planarization layer may have a refractive index greater than that of the substrate.

### BRIEF DESCRIPTION OF THE DRAWINGS

Example embodiments will be more clearly understood from the following brief description taken in conjunction with the accompanying drawings. FIGS. 1 through 6 represent non-limiting, example embodiments as described herein.

FIG. 1 is a sectional view of an organic light emitting diode according to example embodiments of the inventive concept.

FIGS. 2 through 6 are sectional views illustrating a method of forming a textured portion of an organic light emitting diode according to example embodiments of the inventive concept.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

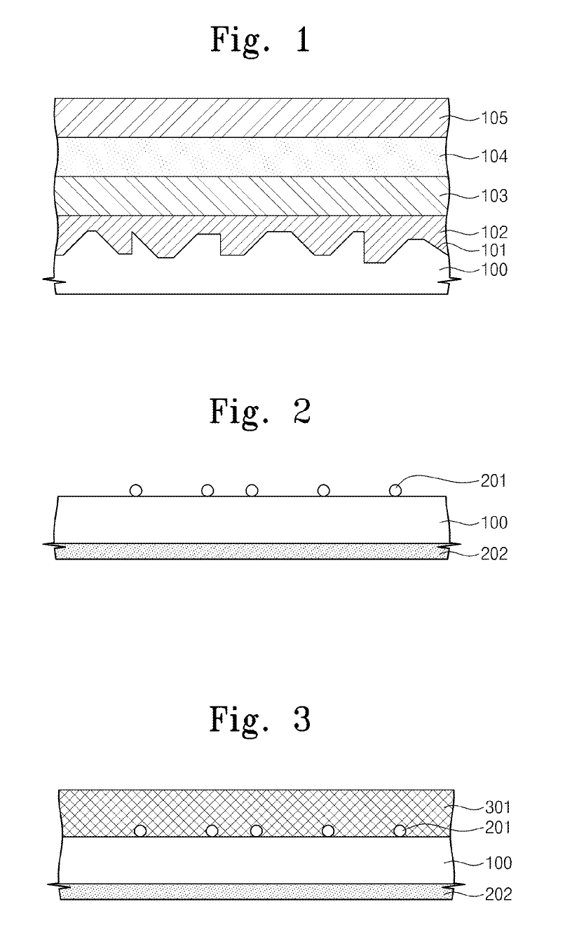

FIG. 1 is a sectional view of an organic light emitting diode according to example embodiments of the inventive concept.

Referring to FIG. 1, an organic light emitting diode according to the inventive concept may include a substrate 100, a first electrode 103, an organic light emitting layer 104, and a second electrode 105. The substrate 100 may include a textured portion 101 facing the first electrode 103 and having a textured surface. A planarization layer 102 may be provided between the textured portion 101 and the first electrode 103 to planarize the textured surface of the substrate 100 formed with the textured portion 101.

The substrate 100 may include an optically transparent material. For example, the substrate 100 may be a glass substrate or a plastic substrate.

In example embodiments, the textured portion 101 of the substrate 100 may be formed to include protruding patterns provided randomly and irregularly on the substrate 100. In addition, the protruding patterns of the textured portion 101 may be formed to have an irregular shape. Each of the protruding patterns may be formed to have a size ranging from 400 nm to 700 nm. The textured portion 101 may lead to a scattering, refraction, and diffraction of the light generated at 104, the organic light emitting layer.

The planarization layer 102 may include at least one of high refractive polymer film, high refractive polymer/nano particle hybrid film, silicon oxide, tin oxide, or tantalum oxide. The planarization layer 102 may have a refractive index greater than that of the substrate 100 provided with the textured portion 101. For example, the planarization layer 102 may be formed of a material having a refractive index of 1.5 or higher. The planarization layer 102 may be formed by one of sputtering techniques, deposition techniques, deposition polymerization techniques, electron beam deposition techniques, plasma deposition techniques, chemical vapor deposition techniques, sol-gel techniques, spin-coating techniques, inkjet techniques, and offset printing techniques.

The first electrode 103 may be one of transparent conductive materials. For example, the first electrode 103 may include one of transparent conductive oxides (TCO) or conductive carbon materials. In example embodiments, the first electrode 103 may include one of indium tin oxide (ITO), indium zinc oxide (IZO), carbon nanotube, or graphene. In other embodiments, the first electrode 103 may include graphene with a thickness ranging from about 1 nm to about 30 nm. Other examples of 103 include conductive polymers, such as Poly(3,4-ethylenedioxythiophene) PEDOT, Poly(3,4-ethylenedioxythiophene) PEDOT: poly(styrene sulfonate) PSS and Poly(4,4-dioctylcyclopentadithiophene). Those conductive polymers may be doped to increase the electrical conductivity.

The organic light emitting layer 104 may include at least one of polyfluorene derivative, (poly)paraphenylenevinylene derivative, polyphenylene derivative, polyvinylcarbazole derivative, polythiophene derivative, anthracene derivative, butadiene derivative, tetracene derivative, distyrylarylene derivative, benzazole derivative, or carbazole. In addition, the organic light emitting layer 104 may be formed of a doped organic light emitting material. In example embodiments, the organic light emitting layer 104 may include an organic material doped with at least one of, for example, xanthene, perylene, cumarine, rhodamine, rubrene, dicyanomethylenepyran, thiopyran, (thia)pyrilium, periflanthene derivative, indenoperylene derivative, carbostyryl, Nile red, or quinacridone. The listed organics are a collective example of known light emitting materials, which may be extended upon the advancement in the related field.

In a structural respect, the organic light emitting layer 104 may be configured to have a single-layered structure or a multi-layered structure including a supplementary layer. For example, the organic light emitting layer 104 may include at least one organic light emitting layer including at least one of the materials enumerated above, and in certain embodiments, may further include a supplementary layer provided to improve luminous efficiency of the organic light emitting layer 104. The supplementary layer may include at least one of a hole injecting layer, a hole transfer layer, an electron transfer layer, or an electron injecting layer. Holes or electrons supplied from the first electrode 103 or the second electrode 105 may be recombined in the organic light emitting layer 104 to generate a light.

The second electrode 105 may be formed of a conductive material. For example, second electrode 105 may include at least one metal, for example, selected from a group consisting of aluminum (Al), silver (Ag), magnesium (Mg), and molybdenum (Mo). In addition, the second electrode 105 may be an optically transparent conductive material. In the case where the second electrode 105 is applied with an external voltage, electrons may be supplied from the second electrode 105 to the organic light emitting layer 104. The second electrode 105 may be configured to allow a light generated from the organic light emitting layer 104 to transmit through or reflect back. Although not shown, an encapsulation layer may be further provided on the second electrode 105.

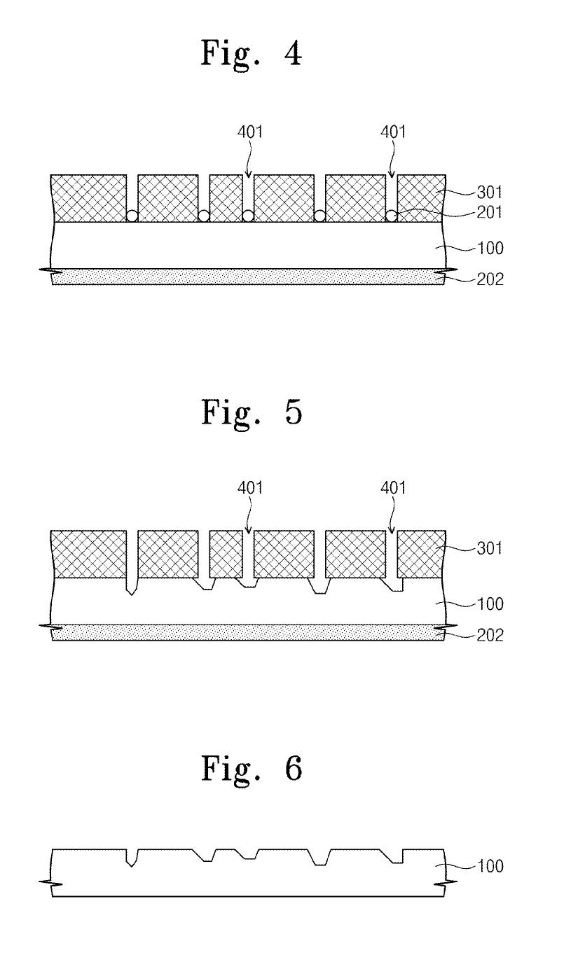

FIGS. 2 through 6 are sectional views illustrating a method of forming a textured portion of an organic light emitting diode according to example embodiments of the inventive concept.

Referring to FIG. 2, nanoparticles 201 may be dispersed on the substrate 100.

Each of the nanoparticles 201 may have a size ranging from 10 nm to 50 nm. Before the dispersion, the nanoparticles 201 may be suspended in a highly volatile organic solvent (e.g., acetone) at a low concentration (e.g., of 0.001% or less). The dispersion of the nanoparticle 201 may include drop-casting the solution containing the nanoparticle 201 on the substrate 100 and drying the solution to obtain randomly dispersed nanoparticles 201 on the substrate 100. The nanoparticles 201 may include one of metal compounds (e.g., ZnO, TiO₂, SnO₂, In₂O₃, NiO, and Al₂O₃) or metals (Ag, Au, Cu, Pt, Ni, Cr, Pd, Mg, Cs, Ca, Sn, Sb, and Pb). The nanoparticles 201 may be formed of a material, which can be etched by a fluorine-based solution. The nanoparticles 201 may be formed by using de-wetting effect of a metallic thin film. For example, the metallic thin film may have a thickness ranging from 10 nm to 50 nm and be formed of at least one of Ag, Au, Cu, Pt, Ni, Cr, Pd, Mg, Cs, Ca, Sn, Sb, or Pb. A de-wetting temperature may be selected between from 200° C. to 600° C. The spacing between the nanoparticles 201 may range from 100 nm to 2000 nm. In example embodiments, a protection layer 202 may be provided on a surface of the substrate 100 opposite to the nanoparticles 201. The protection layer 202 may be formed of a material having an etch-resistance with respect to an etchant for etching the substrate 100 (e.g., a fluorine-based solution).

Referring to FIG. 3, a polymer layer 301 may be formed on the substrate 100 and the nanoparticles 201.

The polymer layer 301 may be formed by a spin-coating process, in which a polymer solution is used. However, the polymer layer 301 may be formed using other layer-forming technique than the spin-coating technique. The polymer solution for the spin-coating process may be prepared by dissolving a polymeric material in a solvent. The polymer layer 301 may include a material exhibiting a de-wetting property on glass. For example, the polymer layer 301 may include at least one of polystyrene (PS), polycarbonate (PC), poly(methyl methacrylate) (PMMA), polyethylene type resin, polyacrylic resin, polyvinyl chloride (PVC), polyvinylpyrrolidone (PVP), polyamide type resin, or epoxy type resin. The polymer solution for the spin-coating process may be prepared to have a polymer concentration ranging from 1% to 5%. The polymer layer 301 may be formed to have a thickness ranging from 50 nm to 2000 nm.

The de-wetting phenomenon of the polymer may occur in the following sequential order. Firstly, holes may be formed in the thickness direction of a layer. Secondly, the holes may be merged to form network and expose large fraction of the substrate. Thirdly, the network dissociate to form droplets. According to example embodiments of the inventive concept, the de-wetting phenomenon may be stopped at the first step to form a polymer mask. In the case where a surface is flat (without the textured pattern), thermal action on the film causes the amplification of the surface perturbation to initiate the de-wetting, which is a spinodal mechanism. According to example embodiments of the inventive concept, the de-wetting phenomenon may occur based on a nucleation and growth mechanism. As a result, the de-wetting phenomenon may occur selectively at preferential positions, where the nanoparticles 201 are provided. In other words, the nucleation and growth mechanism may provide an advantage in realizing a random distribution. In example embodiments, a process using the de-wetting phenomenon may be performed at a temperature higher than the glass transition temperature of a polymer in use.

Referring to FIG. 4, the substrate 100 provided with the polymer layer 301 may be thermally treated.

The nanoparticles 201 may serve as nucleation sites, where de-wetting occurs preferentially. During the thermal treatment, holes 401 may be formed on the positions of the nanoparticles 201 or the nucleation sites. As a result, the polymer layer 301 formed with the holes 401 can be used a polymer mask.

Referring to FIG. 5, the substrate 100 may be etched by using the polymer layer 301 with the holes 401 as an etching mask.

For example, the substrate 100 provided with the polymer layer 301 may be dipped into an etching solution (e.g., for etching glass). As a result, the substrate 100 may be etched by the glass etching solution inflowed through the holes 401. In example embodiments, the glass etching solution may be one of fluorine-based solutions. Due to the presence of the protection layer 202, it is possible to prevent a bottom surface of the substrate 100 from being etched.

Referring to FIG. 6, the polymer layer 301 and the protection layer 202 may be removed by, for example, a solvent dipping method.

Thereafter, as shown in FIG. 1, the planarization layer 102 may be provided on the substrate 100 provided with the textured portion 101 to planarize the textured surface of the protruding portion 101, and then, the first electrode 103, the organic light emitting layer 104, the second electrode 105 may be sequentially provided on the planarization layer 102.

According to example embodiments of the inventive concept, a light extraction mask may be formed without using a vacuum process, and this enables to facilitate and simplify a method of fabricating an organic light emitting diode. In certain embodiments, a high temperature thermal treatment may be omitted, and, in this case, it is possible to reduce a fabrication cost.

While example embodiments of the inventive concepts have been particularly shown and described, it will be understood by one of ordinary skill in the art that variations in form and detail may be made therein without departing from the spirit and scope of the attached claims.

What is claimed is:

1. A method of fabricating an organic light emitting diode, comprising:
preparing a substrate;
forming a textured portion on the substrate, the textured portion including protruding patterns randomly and irregularly arranged on the substrate;
forming a planarization layer on the substrate to planarize the substrate formed with the textured portion;
forming a first electrode on the planarization layer;
forming an organic light emitting layer on the first electrode; and
forming a second electrode on the organic light emitting layer.

2. The method of claim 1, wherein the forming of the textured portion comprises:
dispersing nanoparticles on the substrate to initiate a de-wetting of a polymer;
forming a polymer layer on the nanoparticles;
thermally treating the polymer layer to form a polymer mask; and
etching the substrate using the polymer mask as an etching mask.

3. The method of claim 2, wherein the dispersing of the nanoparticles comprises:
adding the nanoparticles to a volatile liquid solution to prepare a nanoparticle-containing solution; and
dispersing the nanoparticle-containing solution onto the substrate.

4. The method of claim 2, wherein the dispersing of the nanoparticles is performed, at a temperature ranging from 200° C. to 600° C., using a de-wetting effect of a metallic thin film.

5. The method of claim 4, wherein the metallic thin film has a thickness ranging from 10 nm to 50 nm.

6. The method of claim 2, wherein the thermal treatment is performed at a temperature higher than glass transition temperature of the polymer.

7. The method of claim 2, wherein the nanoparticle comprises one of metal compounds or metals.

8. The method of claim 2, wherein a size of the nanoparticle ranges from 10 nm to 50 nm.

9. The method of claim 2, wherein a space between the nanoparticles ranges from 100 nm to 2000 nm.

10. The method of claim 2, wherein a thickness of the polymer layer ranges from 50 nm to 2000 nm.

11. The method of claim 2, wherein the polymer layer comprises at least one of polystyrene (PS), polycarbonate (PC), poly(methyl methacrylate) (PMMA), polyethylene type resin, polyacrylic resin, polyvinyl chloride (PVC), polyvinylpyrrolidone (PVP), polyamide type resin, or epoxy type resin.

12. The method of claim 1, wherein the planarization layer has a refractive index greater than that of the substrate.
